(19) United States
(12) Patent Application Publication
(10) Pub. No.: US 2023/0411414 A1
(43) Pub. Date: Dec. 21, 2023

(54) SEMICONDUCTOR APPARATUS, METHOD FOR MANUFACTURING SEMICONDUCTOR APPARATUS, EQUIPMENT, AND SUBSTRATE

(71) Applicant: CANON KABUSHIKI KAISHA, Tokyo (JP)

(72) Inventors: TATSUNORI KATO, Kanagawa (JP); AKIRA OSETO, Chiba (JP); SAKAE HASHIMOTO, Tokyo (JP)

(21) Appl. No.: 18/334,968

(22) Filed: Jun. 14, 2023

(30) Foreign Application Priority Data
Jun. 21, 2022 (JP) 2022-099665

(51) Int. Cl. H01L 27/146; H01L 27/02

(52) U.S. Cl. CPC H01L 27/14603; H01L 27/0296; H01L 27/14623; H01L 27/14636; H01L 27/14634; H01L 27/1464; H01L 27/14685

(57) ABSTRACT

A semiconductor apparatus includes a semiconductor layer, a wiring layer or a plurality of wiring layers, and a first heat dissipation layer. The semiconductor layer has a first surface and a second surface and includes, between the first surface and the second surface, a semiconductor element and a protection circuit. The wiring layer(s) is disposed at a first-surface side and electrically connected to the protection circuit. The first-surface side is a side where the first surface is located. The first heat dissipation layer is disposed between the wiring layer and the semiconductor layer or between a wiring layer closest to the semiconductor layer, among the wiring layers, and the semiconductor layer, and not electrically connected to the protection circuit. In a plan view taken at the first-surface side, the first heat dissipation layer is disposed at a position of overlapping with at least a part of the protection circuit.

### BACKGROUND OF THE DISCLOSURE

### Field of the Disclosure

The present disclosure relates to a semiconductor apparatus, a method for manufacturing a semiconductor apparatus, equipment, and a substrate.

### Description of the Related Art

In the field of semiconductors such as memories and image sensors, a semiconductor apparatus that includes a protection circuit is known. In Japanese Patent Laid-Open No. 2010-165737, a device configuration for reducing a contact resistance by increasing the grounding area size of a protection circuit and a contact layer is proposed. With this device configuration, heat-dissipation performance improves, and an improvement in protection characteristics of the protection circuit can be expected.

However, in a photoelectric converter disclosed in Japanese Patent Laid-Open No. 2010-165737, there is an issue of an increase in chip area size as the grounding area size of the protection circuit and the contact layer increases.

### SUMMARY OF THE DISCLOSURE

The present disclosure provides a semiconductor apparatus that includes a protection circuit offering improved protection characteristics while suppressing an increase in chip area size.

Provided by a certain aspect of the present disclosure is a semiconductor apparatus that includes a semiconductor layer, a wiring layer or a plurality of wiring layers, and a first heat dissipation layer. The semiconductor layer has a first surface and a second surface and includes, between the first surface and the second surface, a semiconductor element and a protection circuit. The wiring layer, or the plurality of wiring layers, is disposed at a first-surface side and electrically connected to the protection circuit. The first-surface side is a side where the first surface is located. The first heat dissipation layer is disposed between the wiring layer and the semiconductor layer or between a wiring layer that is closest to the semiconductor layer, among the plurality of wiring layers, and the semiconductor layer, and not electrically connected to the protection circuit. In a plan view taken at the first-surface side, the first heat dissipation layer is disposed at a position of overlapping with at least a part of the protection circuit.

Further features of the present disclosure will become apparent from the following description of exemplary embodiments with reference to the attached drawings.

### BRIEF DESCRIPTION OF THE DRAWINGS

FIG. 1 is a plan view for explaining a semiconductor apparatus.

FIG. 2 is a block diagram for explaining a protection circuit in a semiconductor apparatus.

FIG. 3 is a block diagram for explaining a protection circuit in a semiconductor apparatus.

FIG. 4 is a circuit diagram for explaining a protection circuit in a semiconductor apparatus.

FIG. 5 is a circuit diagram for explaining a protection circuit in a semiconductor apparatus.

FIG. 6 is a circuit diagram for explaining a protection circuit in a semiconductor apparatus.

FIG. 7 is a cross-sectional view for explaining a semiconductor apparatus.

FIG. 8 is a plan view for explaining a semiconductor apparatus.

FIG. 9 is a cross-sectional view for explaining a semiconductor apparatus.

FIG. 10 is a cross-sectional view for explaining a semiconductor apparatus according to a first embodiment.

FIG. 11 is a plan view for explaining a semiconductor apparatus according to the first embodiment.

FIG. 12 is a cross-sectional view for explaining a semiconductor apparatus according to the first embodiment.

FIG. 13 is a plan view for explaining a semiconductor apparatus according to the first embodiment.

FIG. 14 is a plan view for explaining a semiconductor apparatus according to the first embodiment.

FIG. 15 is a plan view for explaining a semiconductor apparatus according to the first embodiment.

FIG. 16 is a plan view for explaining a semiconductor apparatus according to the first embodiment.

FIG. 17 is a plan view for explaining a semiconductor apparatus according to the first embodiment.

FIG. 18 is a plan view for explaining a semiconductor apparatus according to the first embodiment.

FIG. 19 is a plan view for explaining a semiconductor apparatus according to the first embodiment.

FIG. 20 is a cross-sectional view for explaining a semiconductor apparatus according to the first embodiment.

FIG. 21 is a cross-sectional view for explaining a semiconductor apparatus according to a second embodiment.

FIG. 22 is a cross-sectional view for explaining a semiconductor apparatus according to the second embodiment.

FIG. 23 is a cross-sectional view for explaining a semiconductor apparatus according to a third embodiment.

FIG. 24 is a plan view for explaining a semiconductor apparatus according to the third embodiment.

FIG. 25 is a plan view for explaining a semiconductor apparatus according to the third embodiment.

FIG. 26 is a cross-sectional view for explaining a semiconductor apparatus according to the third embodiment.

FIG. 27 is a cross-sectional view for explaining a semiconductor apparatus according to a fourth embodiment.

FIG. 28 is a cross-sectional view for explaining a semiconductor apparatus according to the fourth embodiment.

FIG. 29 is a cross-sectional view for explaining a semiconductor apparatus according to a fifth embodiment.

FIG. 30 is a three-dimensional view for explaining heat dissipation layers according to the fifth embodiment.

FIG. 31A is a schematic diagram for explaining equipment according to a sixth embodiment.

FIG. 31B is a schematic diagram for explaining equipment according to the sixth embodiment.

FIG. 31C is a schematic diagram for explaining equipment according to the sixth embodiment.

### DESCRIPTION OF THE EMBODIMENTS

With reference to the drawings, each embodiment will now be described. The embodiments described below shall not be construed to limit the scope of the present disclosure recited in the claims. Though a plurality of features will be described in the embodiments, all of these features are not necessarily indispensable to the present disclosure. Any two or more of the plurality of features may be combined together. In the accompanying drawings, the same reference signs will be assigned to the same or similar components, and the same description will not be given for them. In each of the embodiments described below, a CMOS sensor will be mainly described as an example of a photoelectric converter. However, the scope of each embodiment is not limited to a CMOS sensor. The disclosure may be applied to other examples of a photoelectric converter. The examples include a CCD, an imaging device, a distance measurement device (a device for focus detection or distance measurement using TOF (Time Of Flight) or the like, a light measurement device (a device for measuring an amount of incident light or the like), though not limited thereto.

In this specification, terms that indicate specific directions and/or positions (for example, “top” (above, over, upper, etc.), “bottom” (below, under, lower, etc.), “right” (rightward, etc.), “left” (leftward, etc.), and other terms including them) will be used where necessary. The use of these terms is solely for the purpose of facilitating the understanding of the embodiments described while referring to the drawings, and the technical scope of the present disclosure is not intended to be limited by the meanings of these terms.

In the description below, a “substrate” shall be understood to include not only a semiconductor layer but also insulation films and wiring layers provided on or over the semiconductor layer.

In this specification, the meaning of “connects a member A and a member B electrically” is not limited to a case of direct connection of the member A and the member B. For example, even if there exists another member C connected between the member A and the member B, it is sufficient as long as there is an electric connection therebetween.

In this specification, the term “plane” means a surface extending in a direction parallel to a principal surface of a semiconductor substrate.

The principal surface of a semiconductor substrate could be a light-incident surface of a semiconductor substrate including a photoelectric conversion portion, a surface in which plural ADCs are arranged repeatedly, or a substrate-to-substrate joint surface in a layered-type photoelectric converter. The term “plan view” means a view taken in a direction perpendicular to the principal surface of a semiconductor substrate. The term “cross section” means a sectional face taken in a direction perpendicular to a light-incident surface of a semiconductor layer. The term “cross-sectional view” means a view taken in a direction parallel to the principal surface of a semiconductor substrate.

A metal member such as wiring or a pad described in this specification may be made of a certain single element of metal alone or may be a mixture (alloy). For example, wiring described specifically as copper wiring may be made of copper alone or may have a composition that mainly includes copper and, in addition, includes another component. In addition, for example, a pad connected to an external terminal may be made of aluminum alone or may have a composition that mainly includes aluminum and, in addition, includes another component. The copper wiring and the aluminum pad that are mentioned here are mere examples. The metal mentioned here can be replaced with various kinds of metal. The wiring and the pad that are mentioned here are mere examples of metal members used in a semiconductor apparatus. The disclosure can be applied to other metal members.

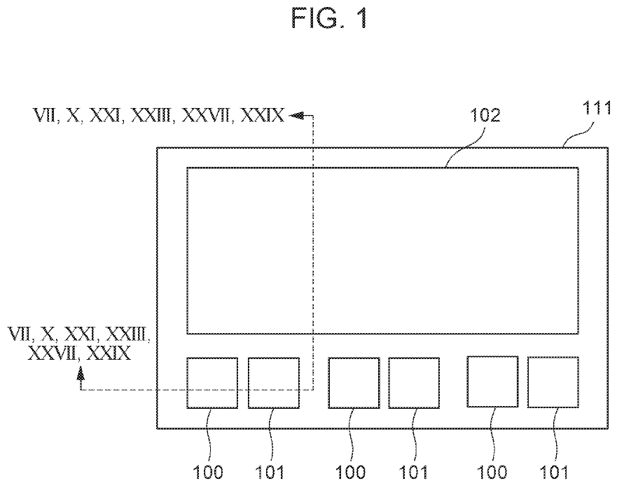

With reference to FIGS. 1 to 9, a structure that is common to a semiconductor apparatus according to embodiments of the present disclosure will now be described.

FIG. 1 is an example of a plan view of a semiconductor apparatus 111. The semiconductor apparatus 111 includes first pads 100, first protection circuits 101, and a semiconductor element 102.

The first pad 100 may be a pad via which a signal generated inside the semiconductor apparatus 111 is outputted to the outside or a pad via which a voltage, etc. supplied from the outside is inputted for the purpose of driving the circuitry of the semiconductor apparatus 111.

A plurality of first pads and a plurality of first protection circuits 101 are provided in the semiconductor apparatus 111. However, they do not have to have the same structure. Nor do they have to be electrically connected to one another. In FIG. 1, in order to make the area size of the semiconductor element 102 larger, the first protection circuits 101 are arranged between the first pads 100; however, they may be arranged between the first pads 100 and the semiconductor element 102.

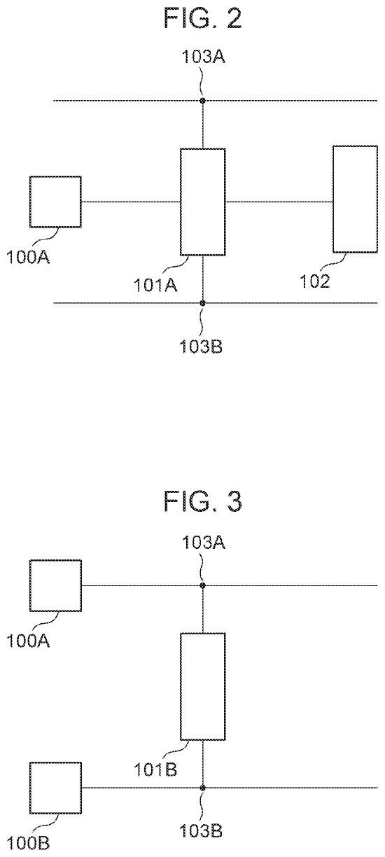

The concept of the first pad 100 encompasses, for example, a second pad 100A and a third pad 100B, which will be described later. The concept of the first protection circuit 101 encompasses, for example, a second protection circuit 101A and a third protection circuit 101B, which will be described later. FIG. 2 is an example of a block diagram illustrating the second protection circuit 101A provided in the semiconductor device 111. The semiconductor apparatus 111 according to certain one embodiment includes the second pad 100A, the second protection circuit 101A, the semiconductor element 102, a first reference potential line 103A, and a second reference potential line 103B.

The second protection circuit 101A is electrically connected to each of the second pad 100A, the semiconductor element 102, the first reference potential line 103A, and the second reference potential line 103B. The second protection circuit 101A is a circuit for protecting the semiconductor element 102 against externally-originated noise such as static electricity or a surge voltage that is inputted from the second pad 100A. Each protection circuit is configured as, for example, a diode, a gate grounded MOS (hereinafter abbreviated as GGMOS), an RC trigger MOS (hereinafter referred to as “power clamp MOS transistor”), or a combination of these elements. In this specification, a description will be given while taking a configuration based on a diode as an example. However, this is a mere example. The configuration is not limited thereto.

The first reference potential line 103A and the second reference potential line 103B are wiring to which a reference potential is applied, for example, power wiring or ground wiring. In this specification, the first reference potential line 103A will be described as power wiring (VDD), and the second reference potential line 103B will be described as ground wiring (GND: ground potential).

The semiconductor element 102 is, for example, an internal circuit provided in the semiconductor apparatus 111, and may include a driver circuit, etc. for amplifying an external signal.

FIG. 3 is an example of a block diagram illustrating the third protection circuit 101B provided in the semiconductor apparatus 111. The third protection circuit 101B is electrically connected to each of the first reference potential line 103A and the second reference potential line 103B. The third protection circuit 101B has no influence on the operation of the semiconductor apparatus 111 when operating usually. On the other hand, when there is an input of externally-originated noise from the second pad 100A via which a voltage is applied to the first reference potential line 103A, the third protection circuit 101B serves as a path through which the externally-originated noise escapes to the second reference potential line 103B, thereby protecting the semiconductor element 102. Moreover, when externally-originated noise is inputted from the second pad 100A and transfers to the first reference potential line 103A through the second protection circuit 101A, the third protection circuit 101B serves as a path through which the externally-originated noise escapes to the second reference potential line 103B, thereby protecting the semiconductor element 102. The semiconductor element 102 may be disposed electrically in connection to the first reference potential line 103A or disposed electrically in connection to the second reference potential line 103B, though not illustrated in FIG. 3.

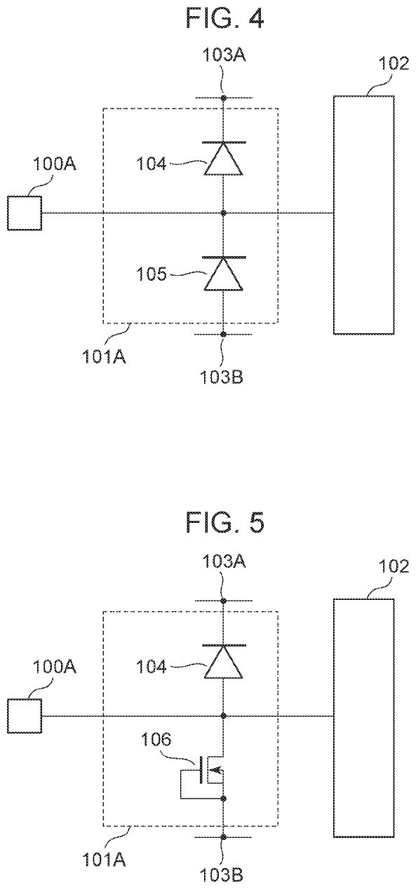

FIG. 4 is an example of a circuit diagram of the second protection circuit 101A. When a power voltage is applied to the first reference potential line 103A, no current, except for a leak current, flows to a first diode 104 and a second diode 105. On the other hand, when an excessive positive voltage is applied to the second pad 100A due to electrostatic discharge, a current flows to the first reference potential line 103A via the first diode 104. When an excessive negative voltage is applied to the second pad 100A, a current flows to the second reference potential line 103B via the second diode 105. With this operation, it is possible to prevent the semiconductor element 102 from being damaged by electrostatic discharge.

FIG. 5 is an example of a circuit diagram of the second protection circuit 101A that is different from the example illustrated in FIG. 4. The difference from FIG. 4 lies in that an n-type GGMOS 106 is provided in place of the second diode 105. In contrast to the structure of an ordinary MOS transistor, the GGMOS 106 has a structure in which its gate and source are short-circuited for grounding (GND). Its drain is connected to the second pad 100A, the first diode 104, and the semiconductor element 102. When a voltage is applied to the drain of the GGMOS 106, no current flows until the voltage exceeds a predetermined value, and, upon exceeding the predetermined value, a current flows (snapback operation).

In FIG. 4, when a negative voltage is applied to the second pad 100A during usual operation of the semiconductor apparatus 111, there is a possibility that an increase in current consumption or a malfunction in operation might be caused by flow of a current to GND via the second diode 105. In the second protection circuit 101A illustrated in FIG. 5, no current flows to the GGMOS even when a negative voltage is applied to the second pad 100A during usual operation. In comparison with the second protection circuit 101A illustrated in FIG. 4, it is possible to reduce effects on usual operation of the semiconductor apparatus 111. In FIG. 5, the first diode 104 may be replaced with a GGMOS. Besides the circuit elements illustrated in FIG. 5, for example, a circuit element such as a resistor or a capacitor may be provided.

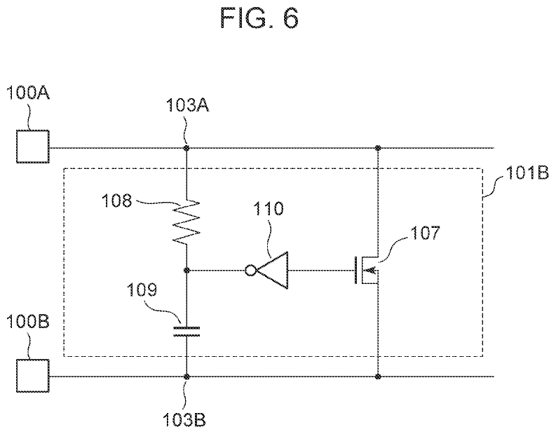

FIG. 6 is an example of a circuit diagram of the third protection circuit 101B. The third protection circuit 101B includes a power clamp MOS transistor. The power clamp MOS transistor includes a series circuit (an RC series circuit) that is made up of a resistor element 108 and a capacitor element 109 that are provided between the first reference potential line 103A and the second reference potential line 103B, and a CMOS inverter 110 whose input terminal is connected to a connection point between the resistor element 108 and the capacitor element 109. The output terminal of the CMOS inverter 110 is connected to the gate electrode of a MOS transistor 107. Though the CMOS inverter 110 illustrated in FIG. 5 has a single-stage configuration, it may have a multiple-stage connection configuration. Though the MOS transistor 107 illustrated therein is an n-type MOS transistor, a p-type MOS transistor may be connected.

The operation of the power clamp MOS transistor will be described below. When an excessive positive voltage is applied to the first reference potential line 103A due to electrostatic discharge, the potential of the input terminal of the inverter will be lower than the potential of the first reference potential line 103A within time of a time constant R x C of the RC series circuit. As a result, the potential of the output terminal of the inverter 110 is a HIGH level, and the MOS transistor 107 is in an ON state. On the other hand, during usual operation, the input terminal of the CMOS inverter is at a HIGH level and the output terminal thereof is at a LOW level, and the MOS transistor 107 is in an OFF state. As described here, the power clamp MOS transistor causes its MOS transistor 107 to turn ON during electrostatic discharge only to allow electric charges to escape, without affecting usual operation of the semiconductor apparatus 111.

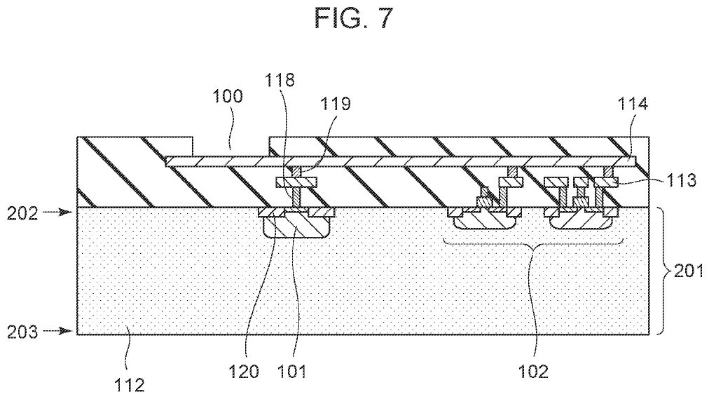

FIG. 7 is an example of a cross-sectional view of a semiconductor apparatus 111 taken along the line VII-VII illustrated in FIG. 1.

The semiconductor apparatus 111 includes a first pad 100, a first wiring layer 113, a second wiring layer 114, a contact layer 118, a first via layer 119, and a semiconductor member 112.

The semiconductor member 112 includes a semiconductor layer 201. The semiconductor layer 201 has a first surface 202 and a second surface 203, and includes a first protection circuit 101, a semiconductor element 102, and an element isolation region 120 between the first surface 202 and the second surface 203. The first protection circuit 101 includes at least a part of the element isolation region 120. The semiconductor member 112 is generally made of silicon but may be a semiconductor member made of a chemical compound including a plurality of elements.

The contact layer 118, the first wiring layer 113, the first via layer 119, and the second wiring layer 114 are provided at a side where the first surface 202 is located in this order of going farther away from the first surface 202. The contact layer 118 connects the first protection circuit 101 and the first wiring layer 113 electrically. The first via layer 119 connects the first wiring layer 113 and the second wiring layer 114 electrically.

The first pad 100 mainly contains metal such as, for example, aluminum. The first wiring layer 113 and the second wiring layer 114 mainly contain metal such as, for example, copper, cobalt, etc.

In FIG. 7, the illustrated layers are limited up to the second wiring layer, and the first pad 100 has an opening over the second wiring layer 114. However, the structure is not limited to this example. The semiconductor apparatus 111 may include any other wiring layer(s) over those illustrated in FIG. 7; however, among the plurality of wiring layers, the first wiring layer 113 is closest to the semiconductor layer 201. In FIG. 7, the first pad 100 is provided at the side where the first surface 202 is located, but may be provided at the side where the second surface 203 is located.

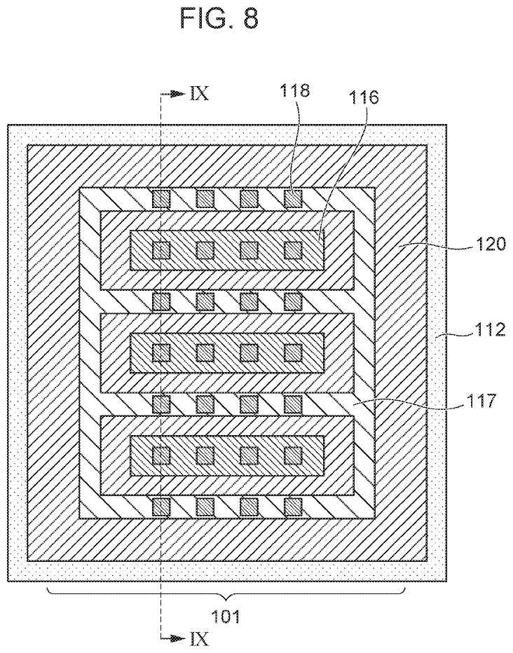

FIG. 8 is an example of a plan view of the neighborhood of the first protection circuit 101 illustrated in FIG. 7. In FIG. 8, upper layers over the first wiring layer 113 illustrated in FIG. 7, and the first wiring layer 113, are not illustrated. The first protection circuit 101 includes an n-type active region 116, a p-type active region 117, and the element isolation region 120. FIG. 8 illustrates nothing more than a general example of an n-type diode and shall not be construed to limit the structure of the protection circuit.

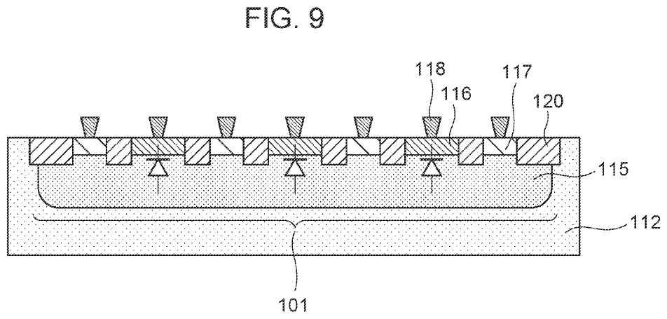

FIG. 9 is an example of a cross-sectional view of the neighborhood of the first protection circuit 101 taken along the line IX-IX illustrated in FIG. 8. In FIG. 9, an example in which an n-type structure is used as the structure of the semiconductor member 112 is illustrated. The first protection circuit 101 includes a p-type well region 115. The p-type well region 115 is formed over an n-type structure, and the n-type active region 116 and the p-type active region 117 are formed in it. The first protection circuit 101 is electrically connected to the first wiring layer 113 via the contact layer 118. Each of the n-type active region 116 and the p-type active region 117 is isolated by the element isolation region 120. The element isolation region 120 has a structure formed by, for example, STI, LOCOS, or the like. The diode is formed between the p-type well region 115 and the n-type active region 116 formed on the p-type well region 115, and the potential of the p-type well region 115 is given by the p-type active region 117.

In the example illustrated in FIG. 7, in a case where an overcurrent flows to the first protection circuit 101 during electrostatic discharge or the like, heat generated or accumulated due to the overcurrent in the first protection circuit 101 is transferred by conduction toward the element isolation region 120, the first surface 202, and the second surface 203. However, if this thermal conduction is insufficient, the electrical conductivity of the first protection circuit 101 will decrease as the temperature rises, and there is a risk that the first protection circuit 101 might fail to fulfill its protection function sufficiently. Moreover, in a case where thermal conduction toward the first surface 202 occurs excessively, there is a risk that the wiring layer, via structure, and/or the contact layer might melt and break, resulting in a malfunction in operation of the semiconductor apparatus 111. In the example described above, thermal conduction toward the second surface 203 via the element isolation region 120 can be expected. However, similarly, it could happen that the protection function of the first protection circuit 101 might deteriorate if thermal conduction toward the second surface 203 via the element isolation region 120 does not occur sufficiently because the element isolation region 120 is provided at the side where the first surface 202 is located.

### First Embodiment

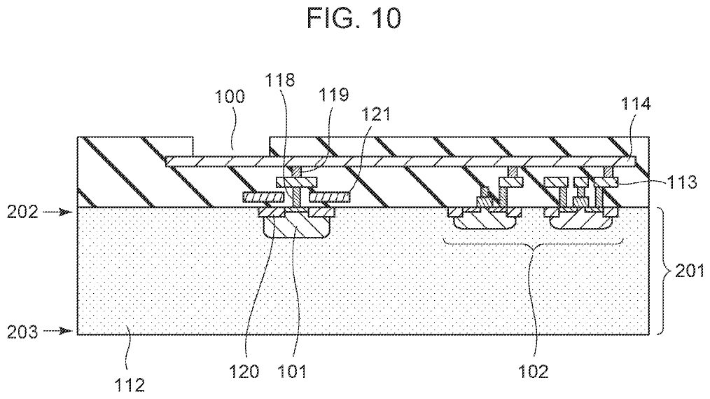

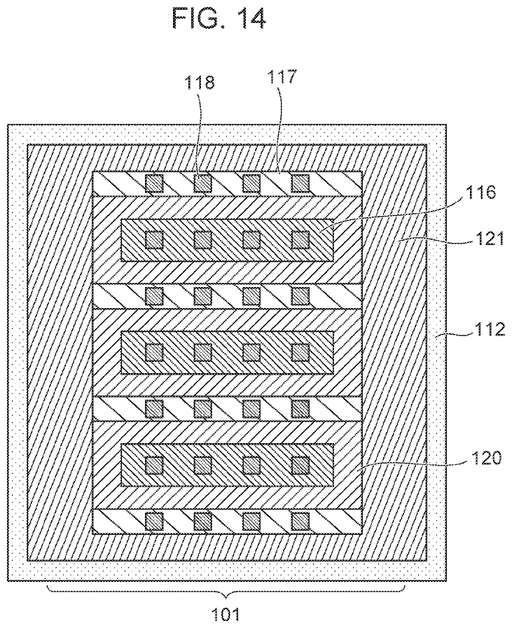

With reference to FIGS. 10 to 20, a structure of the semiconductor apparatus 111 according to a first embodiment of the present disclosure will now be described.

FIG. 10 is an example of a cross-sectional view of a semiconductor apparatus 111 according to a first embodiment taken along the line X-X illustrated in FIG. 1. The present embodiment is different from the example illustrated in FIG. 7 in that a first heat dissipation layer 121 is provided between the first wiring layer 113 and the semiconductor layer 201. In a plan view taken at the side where the first surface 202 is located, the first heat dissipation layer 121 is provided at a position where it overlaps with at least a part of the first protection circuit 101. The first heat dissipation layer 121 is not electrically connected to the first protection circuit 101. In the present embodiment, a description will be given while assuming that the first heat dissipation layer 121 is electrically in a floating state. However, it is sufficient as long as the first heat dissipation layer 121 is not on an electric discharge path of the first protection circuit 101. The first heat dissipation layer 121 may be fixed to potential such as VDD or GND.

For the purpose of being fixed to potential such as VDD or GND, the first heat dissipation layer 121 may be electrically connected to a pad that is not electrically connected to the first protection circuit 101.

The first heat dissipation layer 121 contains a conductive material, for example, contains, at least, a single element alone of metal selected from the group consisting of tungsten, copper, aluminum, titanium, cobalt, and nickel, or an alloy including the metal. The metal element(s) that the first heat dissipation layer 121 mainly contains may be the same as or different from the metal element(s) that the first wiring layer 113 and the second wiring layer 114 mainly contain.

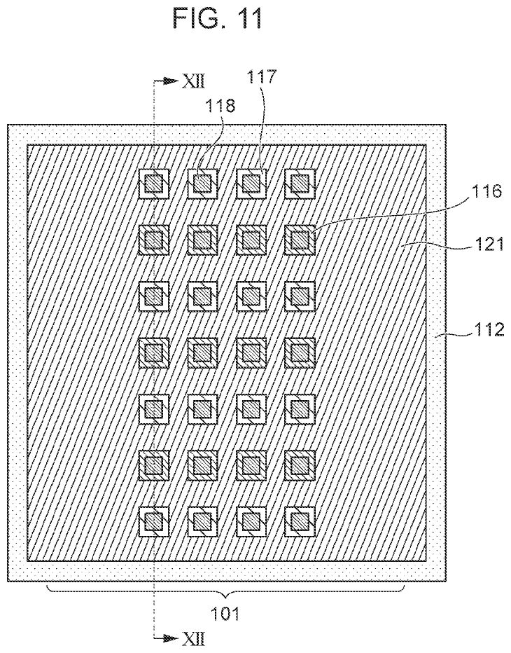

FIG. 11 is an example of a plan view of the neighborhood of the first protection circuit 101 illustrated in FIG. 10. In FIG. 11, upper layers over the first wiring layer 113, and the first wiring layer 113, are not illustrated. In FIG. 11, the first heat dissipation layer 121 is provided in such a way as to cover the first protection circuit 101 in its entirety, except for the regions of the contact layer 118. That is, in a plan view taken at the side where the first surface 202 is located, the contact layer 118 is provided inside regions surrounded by the first heat dissipation layer 121.

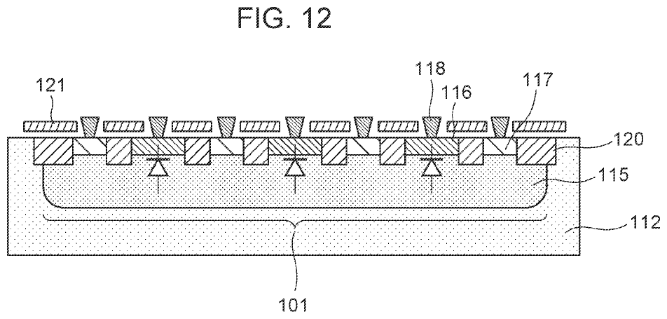

FIG. 12 is an example of a cross-sectional view of the neighborhood of the first protection circuit 101 taken along the line XII-XII illustrated in FIG. 11. According to the first embodiment, in a case where an overcurrent flows to the first protection circuit 101 during electrostatic discharge or the like, heat generated or accumulated due to the overcurrent is released toward the first surface 202 by the first heat dissipation layer 121, and this makes it possible to suppress an increase in the temperature of the first protection circuit 101. By this means, it is possible to increase the electrical conductivity of the first protection circuit 101 and improve its protection characteristics.

Moreover, in a case where thermal conduction toward the first wiring layer 113 occurs excessively, providing the first heat dissipation layer 121 between the first protection circuit 101 and the first wiring layer 113 promotes heat dissipation; therefore, it is possible to suppress thermal conduction to the first wiring layer 113 and wiring layers provided over it. Even if the first heat dissipation layer 121 melts and breaks, it is possible to reduce an influence on circuit operation, as compared with a case where the first wiring layer 113 melts and breaks. Therefore, it is possible to realize a more reliable first protection circuit 101 whose wiring layer, via layer, and contact layer are harder to melt and break in comparison with the first protection circuit 101 according to the example illustrated in FIG. 7.

As described above, with the semiconductor apparatus 111 according to the present embodiment, improved protection characteristics can be expected while suppressing an increase in chip area size because the area size of the first protection circuit 101 is less likely to increase in comparison with the area size of the first protection circuit 101 according to the example illustrated in FIG. 7.

Moreover, with the semiconductor apparatus 111 according to the present embodiment, since the electrical conductivity of the first protection circuit 101 increases, it is possible to realize characteristics equivalent to the characteristics of the first protection circuit 101 according to the example illustrated in FIG. 7 by the first protection circuit 101 having a more compact structure than in the example illustrated in FIG. 7.

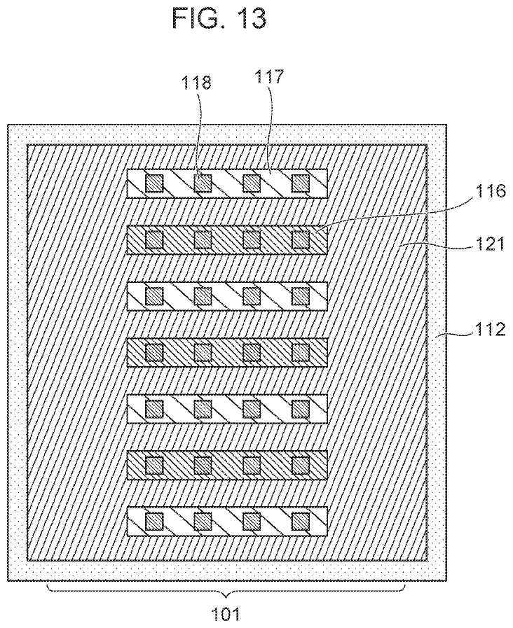

Examples different from the example of a plan view of the neighborhood of the first protection circuit 101 illustrated in FIG. 11 are illustrated in FIGS. 13, 14, and 15. In comparison with FIG. 11, in FIGS. 13, 14, and 15, the degree of freedom in layout of the contact layer 118 improves, and it is possible to increase a space margin between the contact layer 118 and the first heat dissipation layer 121. Therefore, it is possible to reduce the possibility of contact of the contact layer 118 and the first heat dissipation layer 121 due to manufacturing variation and reduce the risk of a malfunction in operation of the semiconductor apparatus 111.

As illustrated in FIGS. 11, 13, 14, and 15, various configurations are conceivable for the layout of the first heat dissipation layer 121. In a plan view taken at the side where the first surface 202 is located, the first heat dissipation layer 121 may be provided between a plurality of contact layers 118. In a plan view taken at the side where the first surface 202 is located, the contact layer 118 may be provided between a plurality of first heat dissipation layers 121. In a plan view taken at the side where the first surface 202 is located, the first heat dissipation layer 121 may be provided at a position where it overlaps with at least a part of the well region 115. In a plan view taken at the side where the first surface 202 is located, the first heat dissipation layer 121 may be provided at a position where it overlaps with at least a part of the n-type active region 116 and the p-type active region 117. In a plan view taken at the side where the first surface 202 is located, the first heat dissipation layer 121 may be provided at a position where it overlaps with at least a part of the well region 115 and overlaps with at least a part of the n-type active region 116 and the p-type active region 117. In a plan view taken at the side where the first surface 202 is located, the first heat dissipation layer 121 may be provided at a position where it overlaps with an end portion of the well region 115.

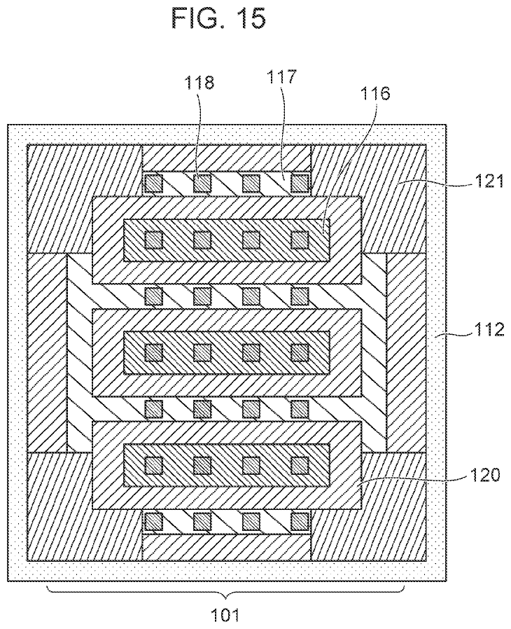

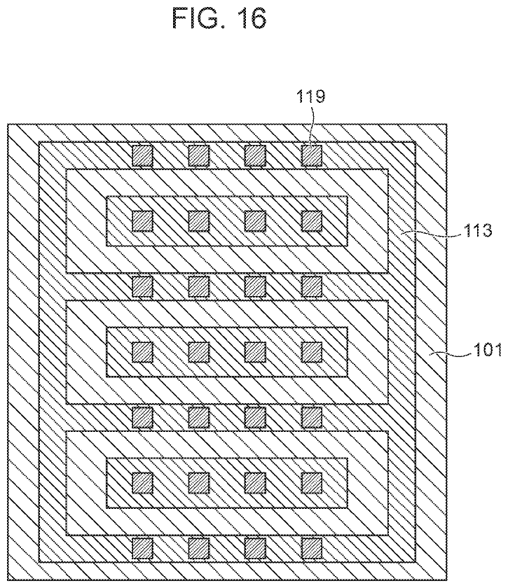

As an example of an improvement in the degree of freedom in layout, effects of FIG. 15 will now be described while referring to FIGS. 16 to 20. Though a structure whose illustrated layers are limited up to a third wiring layer 123 will be described, this is a non-limiting example. A second via layer 122 connects the second wiring layer 114 and the third wiring layer 123 electrically. FIGS. 16 to 19 are plan views, each illustrating some layers, of the layout illustrated in FIG. 15. In FIGS. 16 to 18, the first heat dissipation layer 121 is not illustrated.

FIG. 16 is a plan view illustrating the neighborhood of the first protection circuit 101, with upper layers over the second wiring layer 114 omitted, and with the second wiring layer 114 also omitted, in the layout illustrated in FIG. 15; the first protection circuit 101, the first wiring layer 113, and the first via layer 119 are illustrated therein.

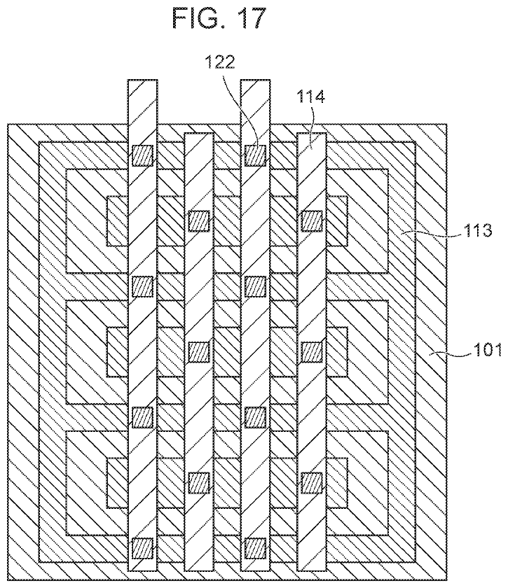

FIG. 17 is a plan view illustrating the neighborhood of the first protection circuit 101, with upper layers over the third wiring layer 123 omitted, and with the third wiring layer 123 also omitted, in the layout illustrated in FIG. 15; the first protection circuit 101, the first wiring layer 113, the second wiring layer 114, and the second via layer 122 are illustrated therein.

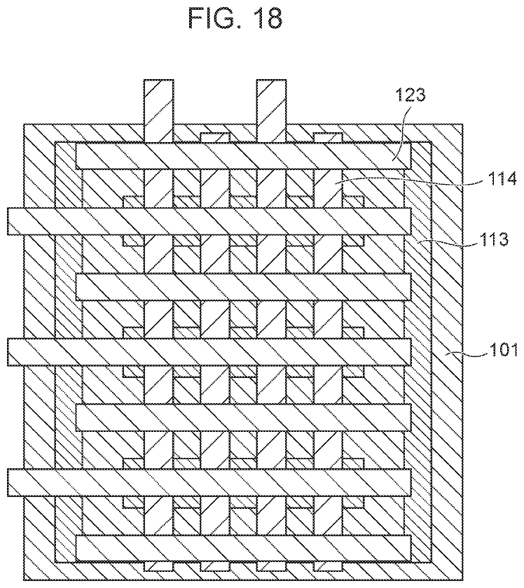

FIG. 18 is a plan view illustrating the neighborhood of the first protection circuit 101, with upper layers over the third wiring layer 123 omitted, in the layout illustrated in FIG. 15; the first protection circuit 101, the first wiring layer 113, the second wiring layer 114, and the third wiring layer 123 are illustrated therein.

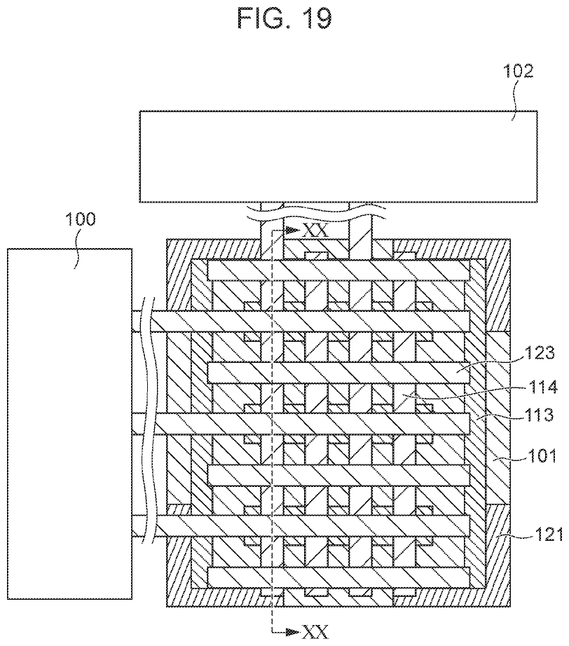

FIG. 19 is a plan view illustrating the first pad 100, the semiconductor element 102, and the first heat dissipation layer 121 in addition to those illustrated in FIG. 18.

In FIG. 19, the first pad 100 is connected to the first protection circuit 101 via the third wiring layer 123. In addition, the first protection circuit 101 is connected to the semiconductor element 102 via the second wiring layer 114. Therefore, the first pad 100 is connected to the semiconductor element 102 via the first protection circuit 101. In FIG. 19, the first pad 100, the first protection circuit 101, and the semiconductor element 102 are illustrated in such a way as to have a positional relationship that is in accordance with the layout illustrated in FIG. 1; however, the first protection circuit 101 may be disposed between the first pad 100 and the semiconductor element 102 that face each other.

When wiring paths from the first pad 100 to the semiconductor element 102 are considered, there are differences in resistance among the wiring paths in accordance with differences in wiring path length. The differences in wiring path length are significant especially in the neighborhood of corner portions of the first protection circuit 101 because the shortest wiring path and the longest wiring path exist thereat. For this reason, in a case where an overcurrent flows from the first pad 100 to the semiconductor element 102 via the first protection circuit 101 during electrostatic discharge or the like, there is a risk that current density might be imbalanced due to the differences in resistance among the wiring paths. As a result, there is a risk that an issue such as melting and breaking of the wiring layer, via structure, and/or the contact layer might occur in the neighborhood of corner portions of the first protection circuit 101 due to heat generation. By contrast, as illustrated in FIG. 19, the first heat dissipation layer 121 is disposed in such a way as to overlap with at least the neighborhood of corner portions of the first protection circuit 101 in a plan view taken at the side where the first surface 202 is located. This makes it possible to provide the first protection circuit 101 that offers improved protection characteristics while suppressing an increase in chip area size. Moreover, since the first heat dissipation layer 121 is disposed in such a way as to cover the neighborhood of corner portions of the first protection circuit 101, the first protection circuit 101 realizes a high degree of freedom in layout without being limited by the arrangement of the first heat dissipation layer 121.

The layout illustrated in FIGS. 16, 17, 18, and 19 is nothing more than a non-limiting example.

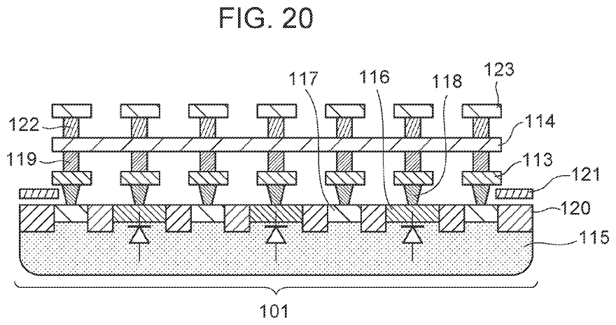

FIG. 20 is an example of a cross-sectional view of the neighborhood of the first protection circuit 101 taken along the line XX-XX illustrated in FIG. 19.

### Second Embodiment

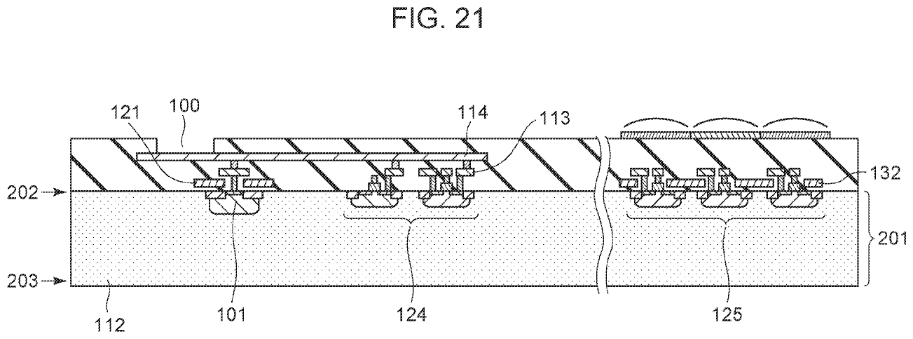

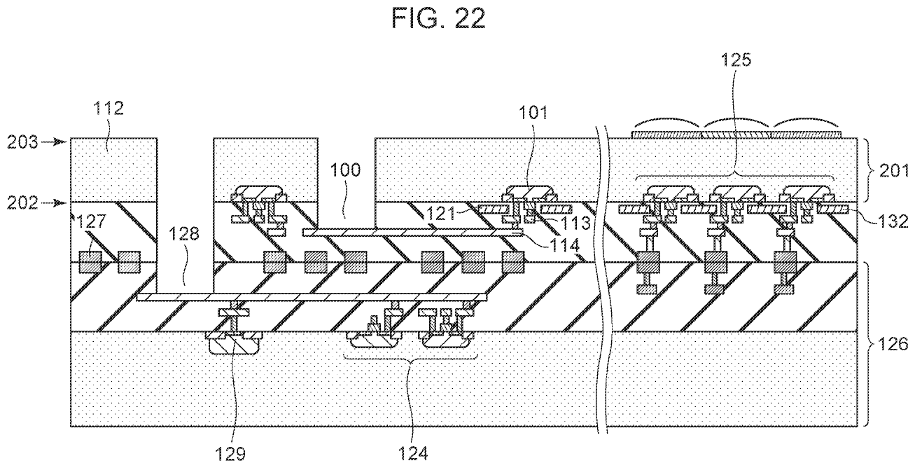

With reference to FIGS. 21 and 22, the structure of a semiconductor apparatus 111 according to a second embodiment of the present disclosure will now be described, with a focus on the difference from the first embodiment. The same reference signs will be assigned to the same components as those of the first embodiment, and explanation about these components may be omitted or simplified.

FIG. 21 is an example of a cross-sectional view of a semiconductor apparatus 111 according to a second embodiment taken along the line XXI-XXI illustrated in FIG. 1. The difference from the first embodiment lies in that the semiconductor element 102 includes a photoelectric conversion portion 125 and a peripheral circuit 124 configured to process a signal detected by the photoelectric conversion portion 125. The photoelectric conversion portion 125 includes, for example, a light shielding film 132 for the purpose of blocking light. In a plan view taken at the side where the first surface 202 is located, the light shielding film 132 is disposed at a position where it overlaps with at least a part of the photoelectric conversion portion 125.

According to the second embodiment, forming the light shielding film 132 and the first heat dissipation layer 121 in concurrent steps respectively makes it unnecessary to develop a new process and makes it possible to reduce development cost and manufacturing cost. The step of forming the light shielding film 132 and the step of forming the first heat dissipation layer 121 do not necessarily have to be executed at the same time. At least a partial overlapping of their steps suffices. In the semiconductor apparatus 111 illustrated in FIG. 21, light may enter the photoelectric conversion portion 125 through the first surface 202 or enter the photoelectric conversion portion 125 through the second surface 203. The semiconductor apparatus 111 illustrated in FIG. 21 has a single-layer structure.

In FIG. 22, the structure of FIG. 21, which is a single-layer structure, is modified into a stacked structure. FIG. 22 illustrates a structure in which a circuit substrate 126 including the peripheral circuit 124 is stacked on (under) the semiconductor layer 201. The semiconductor member 112 is electrically connected to the circuit substrate 126 via a joint portion 127. The semiconductor member 112 includes at least the photoelectric conversion portion 125 and the first protection circuit 101. The circuit substrate 126 includes at least the peripheral circuit 124. In FIG. 22, the first pad 100 is provided in the semiconductor member 112, a fourth pad 128 is provided in the circuit substrate 126, and the first pad 100 is connected to the first protection circuit 101. There may be a connection from the fourth pad 128 to the first protection circuit 101 via the joint portion 127. The circuit substrate 126 may include wiring layers and a fourth protection circuit 129, and, though not illustrated, a heat dissipation layer may be provided between, among the wiring layers of the circuit substrate 126, the nearest one, which is closest to the semiconductor layer, and the semiconductor layer. In a case where a heat dissipation layer is provided, in a plan view taken at the side where the first surface 202 is located, the heat dissipation layer is disposed at a position where it overlaps with at least a part of the fourth protection circuit 129.

### Third Embodiment

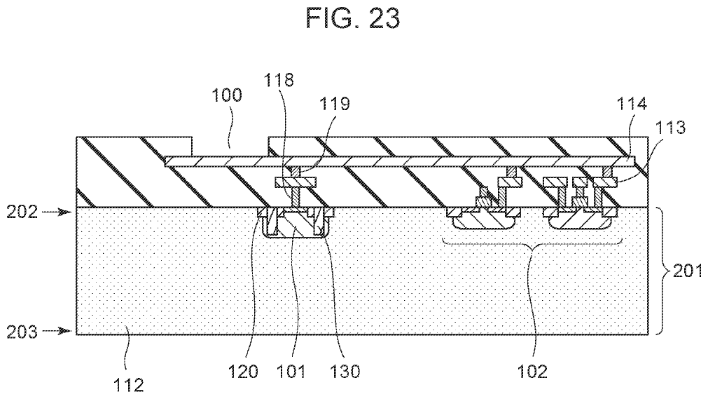

With reference to FIGS. 23 to 26, the structure of a semiconductor apparatus 111 according to a third embodiment of the present disclosure will now be described, with a focus on the difference from the first embodiment and the second embodiment. The same reference signs will be assigned to the same components as those of the first embodiment and the second embodiment, and explanation about these components may be omitted or simplified.

FIG. 23 is a cross-sectional view of a semiconductor apparatus 111 according to a third embodiment taken along the line XXIII-XXIII illustrated in FIG. 1. The third embodiment is different from the first embodiment and the second embodiment in terms of the structure of a heat dissipation layer. In the third embodiment, a second heat dissipation layer 130 is disposed in contact with the element isolation region 120 between the first surface 202 and the second surface 203. The first protection circuit 101 is provided at a first depth from the first surface 202. Similarly, the second heat dissipation layer 130 is also provided at the first depth from the first surface 202.

The second heat dissipation layer 130 contains a conductive material, for example, contains, at least, a single element alone of metal selected from the group consisting of tungsten, copper, aluminum, titanium, cobalt, and nickel, or an alloy mainly including the metal, or a metal-and-polysilicon compound. The metal element(s) that the second heat dissipation layer 130 mainly contains may be the same as or different from the metal element(s) that the first wiring layer 113 and the second wiring layer 114 mainly contain.

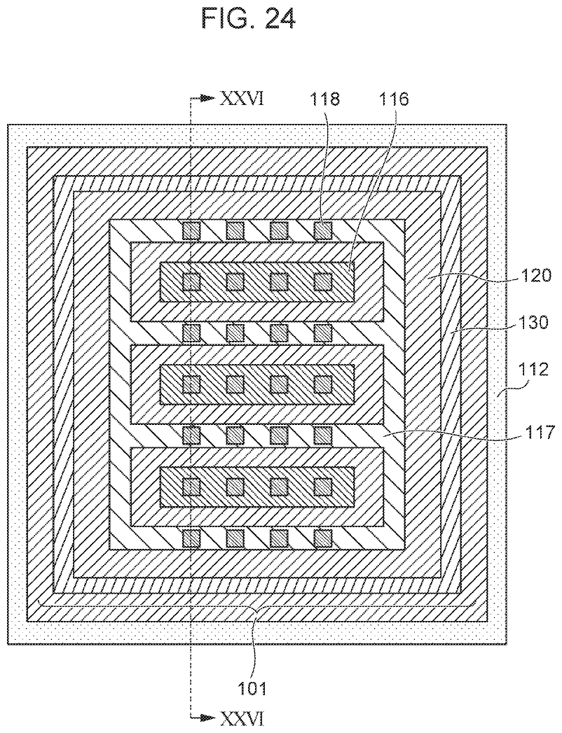

FIG. 24 is an example of a plan view of the neighborhood of the first protection circuit 101 illustrated in FIG. 23. In FIG. 24, upper layers over the first wiring layer 113, and the first wiring layer 113, are not illustrated. In FIG. 24, the second heat dissipation layer 130 is disposed at a periphery in such a way as to surround the contact layer 118.

That is, in a plan view taken at the side where the first surface 202 is located, the contact layer 118 is disposed inside regions surrounded by the second heat dissipation layer 130. The second heat dissipation layer 130 may be disposed inside the first protection circuit 101 or disposed outside the first protection circuit 101.

An example different from the example of a plan view of the neighborhood of the first protection circuit 101 illustrated in FIG. 24 is illustrated in FIG. 25. FIG. 25 is different from FIG. 24 in that the second heat dissipation layer 130 has a shape of a plurality of round columns. In FIG. 25, it is possible to make the surface area size of the second heat dissipation layer 130 larger than that of FIG. 24. Therefore, a further improvement in heat-dissipation performance can be expected. The columnar shape illustrated in FIG. 25 is nothing more than a non-limiting example.

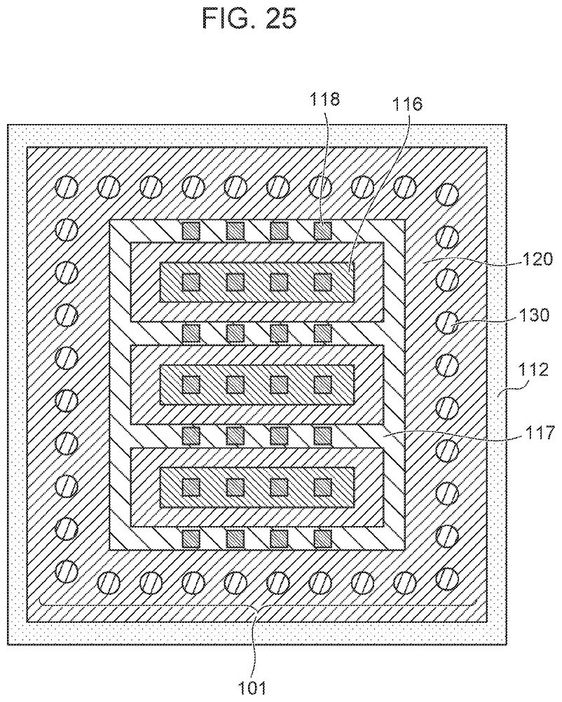

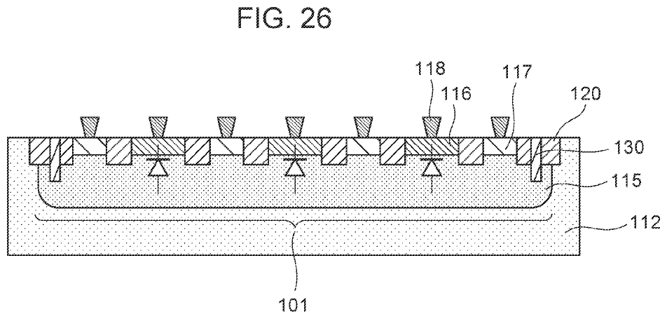

FIG. 26 is an example of a cross-sectional view of the neighborhood of the first protection circuit 101 taken along the line XXVI-XXVI illustrated in FIG. 24. According to the third embodiment, in a case where an overcurrent flows to the first protection circuit 101 during electrostatic discharge or the like, heat generated or accumulated due to the overcurrent is released toward the second surface 203 via the second heat dissipation layer 130, and this makes it possible to suppress an increase in the temperature of the first protection circuit 101. By this means, it is possible to increase the electrical conductivity of the first protection circuit 101 and improve its protection characteristics. By forming the second heat dissipation layer 130 in such a way as to have a greater depth in a depth direction of the semiconductor layer 201, it is possible to increase the surface area size of the second heat dissipation layer 130, thereby further improving heat-dissipation performance.

As described above, with the semiconductor apparatus 111 according to the present embodiment, improved protection characteristics can be expected while suppressing an increase in chip area size because the area size of the first protection circuit 101 is less likely to increase in comparison with the area size of the first protection circuit 101 according to the example illustrated in FIG. 7.

Moreover, with the semiconductor apparatus 111 according to the present embodiment, since the electrical conductivity of the first protection circuit 101 increases, it is possible to realize characteristics equivalent to the characteristics of the first protection circuit 101 according to the example illustrated in FIG. 7 by the first protection circuit 101 having a more compact structure than in the example illustrated in FIG. 7.

### Fourth Embodiment

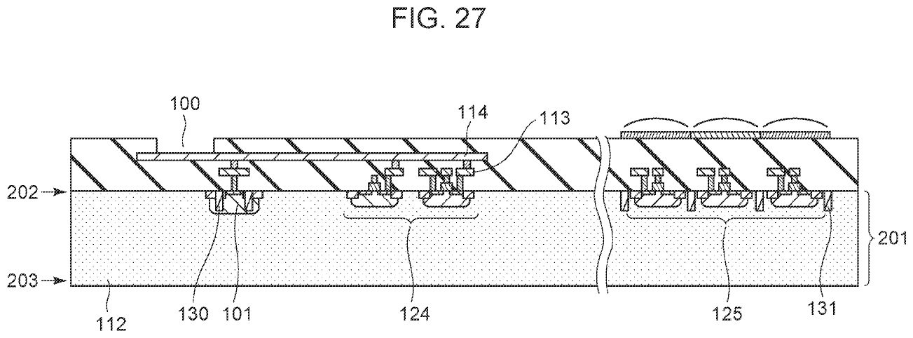

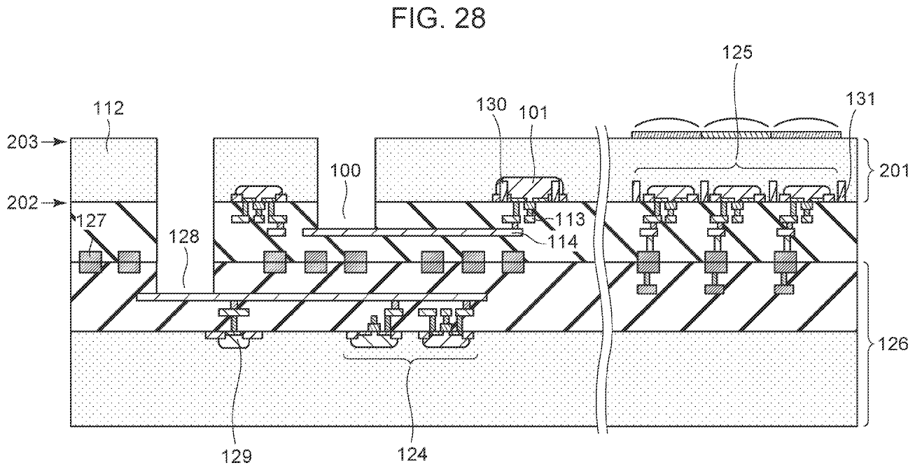

With reference to FIGS. 27 and 28, the structure of a semiconductor apparatus 111 according to a fourth embodiment of the present disclosure will now be described, with a focus on the difference from the first to third embodiments. The same reference signs will be assigned to the same components as those of the first to third embodiments, and explanation about these components may be omitted or simplified.

FIG. 27 is a cross-sectional view of a semiconductor apparatus 111 according to a fourth embodiment taken along the line XXVII-XXVII illustrated in FIG. 1. The photoelectric conversion portion 125 includes, for example, a separation portion 131 for the purpose of noise reduction. The separation portion 131 is provided at a first depth in the semiconductor layer 201.

According to the fourth embodiment, forming the separation portion 131 and the second heat dissipation layer 130 in concurrent steps respectively makes it unnecessary to develop a new process and makes it possible to reduce development cost and manufacturing cost. The step of forming the separation portion 131 and the step of forming the second heat dissipation layer 130 do not necessarily have to be executed at the same time. At least a partial overlapping of their steps suffices. In the semiconductor apparatus 111 illustrated in FIG. 27, light may enter the photoelectric conversion portion 125 through the first surface 202 or enter the photoelectric conversion portion 125 through the second surface 203. The semiconductor apparatus 111 illustrated in FIG. 27 has a single-layer structure.

In FIG. 28, the structure of FIG. 27, which is a single-layer structure, is modified into a stacked structure. FIG. 28 illustrates a structure in which a circuit substrate 126 including the peripheral circuit 124 is stacked on the semiconductor layer 201. The semiconductor member 112 is electrically connected to the circuit substrate 126 via a joint portion 127. The semiconductor member 112 includes at least the photoelectric conversion portion 125 and the first protection circuit 101. The circuit substrate 126 includes at least the peripheral circuit 124. In FIG. 28, the first pad 100 is provided in the semiconductor member 112, a fourth pad 128 is provided in the circuit substrate 126, and the first pad 100 is connected to the first protection circuit 101. There may be a connection from the fourth pad 128 to the first protection circuit 101 via the joint portion 127. The circuit substrate 126 may include a fourth protection circuit 129, and, though not illustrated, the circuit substrate 126 may include a heat dissipation layer in contact with the element isolation region.

In a case where a heat dissipation layer is included, the heat dissipation layer is disposed at the same depth as the fourth protection circuit 129.

### Fifth Embodiment

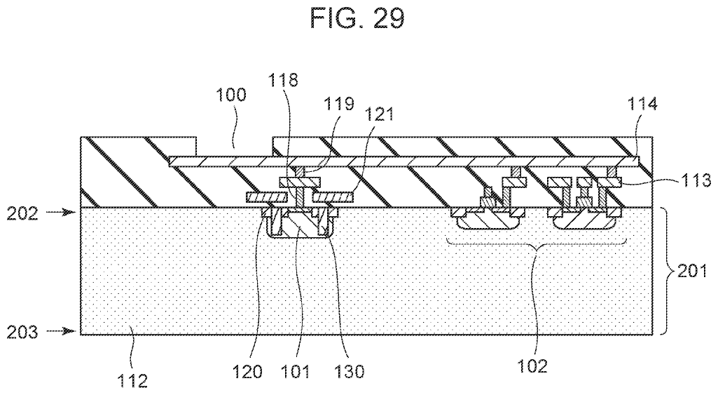

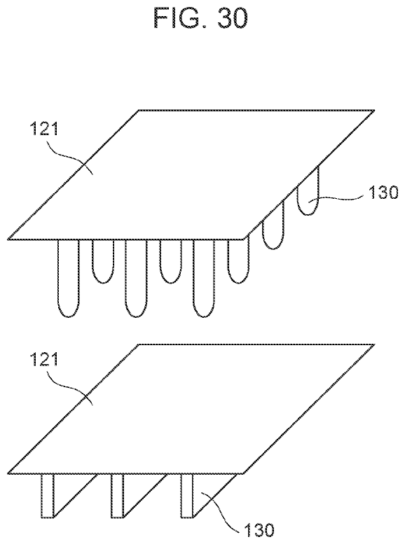

With reference to FIGS. 29 and 30, the structure of a semiconductor apparatus 111 according to a fifth embodiment of the present disclosure will now be described, with a focus on the difference from the first to fourth embodiments. The same reference signs will be assigned to the same components as those of the first to fourth embodiments, and explanation about these components may be omitted or simplified.

FIG. 29 is a cross-sectional view of a semiconductor apparatus 111 according to a fifth embodiment taken along the line XXIX-XXIX illustrated in FIG. 1. The structure according to the fifth embodiment is a combination of the structure according to the first embodiment illustrated in FIG. 10 and the structure according to the third embodiment illustrated in FIG. 23. That is, the structure according to the fifth embodiment includes the first heat dissipation layer 121 disposed between the semiconductor layer 201 and the first wiring layer 113, and the second heat dissipation layer 130 disposed between the first surface 202 and the second surface 203. The first heat dissipation layer 121 and the second heat dissipation layer 130 may be electrically connected or not electrically connected.

FIG. 30 illustrates an example of a three-dimensional structure in a case where the first heat dissipation layer 121 and the second heat dissipation layer 130 are electrically connected in FIG. 29. By combining the first embodiment and the third embodiment and forming a comb-like fin shape or a pinholder shape as in a so-called heat sink structure, it is possible to increase the surface area size of the heat dissipation layer and further improve heat-dissipation performance.

The fifth embodiment makes it possible to make the protection characteristics of the first protection circuit 101 higher than in the first embodiment and the third embodiment. Alternatively, as compared with the first embodiment and the third embodiment, it is possible to realize characteristics equivalent to the characteristics of the first protection circuit 101 according to the first embodiment and the third embodiment by the first protection circuit 101 having a more compact structure.

Though not illustrated, similarly to the second embodiment and the fourth embodiment, the semiconductor element 102 may include a photoelectric conversion portion 125 and a peripheral circuit 124 configured to process a signal detected by the photoelectric conversion portion 125. In the semiconductor apparatus 111 illustrated in FIG. 29, light may enter the photoelectric conversion portion 125 through the first surface 202 or enter the photoelectric conversion portion 125 through the second surface 203. Though the semiconductor apparatus 111 illustrated in FIG. 29 has a single-layer structure, a circuit substrate including the peripheral circuit 124 may be stacked on the semiconductor layer 201.

### Sixth Embodiment

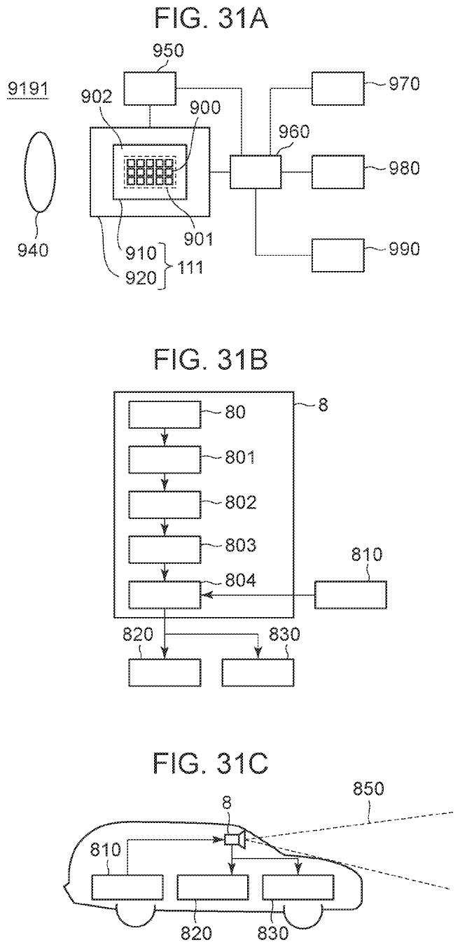

A sixth embodiment can be applied to any of the first to fifth embodiments. FIG. 31A is a schematic diagram for explaining equipment 9191 that is provided with the semiconductor apparatus 111 according to an embodiment. The equipment 9191 that is provided with the semiconductor apparatus 111 will now be described in detail. The semiconductor apparatus 111 can include a semiconductor device 910. The semiconductor device 910 has a pixel area 901 in which pixel circuits 900 including photoelectric conversion units are arranged in a matrix. The semiconductor device 910 can have a peripheral area 902 around the pixel area 901. Circuits other than the pixel circuits 900 can be arranged in the peripheral area 902. The semiconductor apparatus 111 may include, besides a semiconductor device 910 that includes the semiconductor layer 201, a package 920 in which the semiconductor device 910 is housed. The package 920 may include a base body to which the semiconductor device 910 is fixed, and a cover body such as a glass cover facing the semiconductor device 910. The package 920 may further include a joint member such as a bonding wire, a bump, or the like for connection between a terminal provided on the base body and a terminal provided on the semiconductor device 910.

The equipment 9191 may include at least one selected from the group consisting of an optical apparatus 940, a control apparatus 950, a processing apparatus 960, a display apparatus 970, a storage apparatus 980, and a mechanical apparatus 990. The optical apparatus 940 is co-operable with the semiconductor apparatus 111. The optical apparatus 940 is, for example, a lens, a shutter, and/or a mirror. The control apparatus 950 controls the semiconductor apparatus 111. The control apparatus 950 is, for example, a semiconductor apparatus such as an ASIC.

The processing apparatus 960 processes signals outputted from the semiconductor apparatus 111. The processing apparatus 960 is a semiconductor apparatus such as a CPU or an ASIC for constituting an analog front end (AFE) or a digital front end (DFE). The display apparatus 970 is an EL display apparatus or a liquid crystal display apparatus that displays information (images) obtained by the semiconductor apparatus 111. The storage apparatus 980 is a magnetic device or a semiconductor device that stores information (images) obtained by the semiconductor apparatus 111. The storage apparatus 980 is a volatile memory such as an SRAM or a DRAM, or a non-volatile memory such as a flash memory or a hard disk drive.

The mechanical apparatus 990 includes a movable unit or a propelling unit such as a motor or an engine. In the equipment 9191, a signal outputted from the semiconductor apparatus 111 is displayed on the display apparatus 970 or transmitted to the outside by a communication apparatus (not illustrated) with which the equipment 9191 is provided. For this purpose, it is preferable if the equipment 9191 further includes the storage apparatus 980 and the processing apparatus 960 aside from a storage circuit and an arithmetic operation circuit of the semiconductor apparatus 111. The mechanical apparatus 990 may be controlled based on a signal outputted from the semiconductor apparatus 111.

The equipment 9191 is suitable for electronic equipment such as an information terminal having an image-capturing function (for example, a smartphone or a wearable terminal) or a camera (for example, a lens-interchangeable camera, a compact camera, a video camera, or a surveillance camera). The mechanical apparatus 990 in a camera is capable of driving components of the optical apparatus 940 for the purpose of zooming, focusing, and shutter operation. Alternatively, the mechanical apparatus 990 in a camera is capable of moving the semiconductor apparatus 111 for the purpose of anti-vibration operation.

The equipment 9191 may be transportation equipment such as a vehicle, a vessel, or a flying entity. The mechanical apparatus 990 in transportation equipment can be used as a moving apparatus. The equipment 9191 serving as transportation equipment is suited for transportation of the semiconductor apparatus 111, or driving assistance (manipulation assistance) and/or automation by means of an image-capturing function. The processing apparatus 960 for driving assistance (manipulation assistance) and/or automation is capable of, based on information obtained by the semiconductor apparatus 111, performing processing for operating the mechanical apparatus 990 serving as a moving apparatus. Alternatively, the equipment 9191 may be medical equipment such as an endoscope, measurement such as a distance measurement sensor, analysis equipment such as an electron microscope, business equipment such as a copier, or industrial equipment such as a robot.

The embodiment described above makes it possible to obtain good pixel characteristics. Therefore, it is possible to increase the value of the semiconductor apparatus. The meaning of “increase the value” mentioned here corresponds to at least one selected from the group consisting of adding a function, improving performance, improving characteristics, enhancing reliability, increasing manufacturing yield, reducing environmental burden, reducing cost, reducing size, and reducing weight.

Therefore, if the semiconductor apparatus 111 according to the present embodiment is used in the equipment 9191, it is possible to enhance the equipment's value. For example, mounting the semiconductor apparatus 111 in transportation equipment makes it possible to obtain excellent performance when an image of the outside of the transportation equipment is captured or when measurement of an outside environment is performed. Therefore, when manufacturing and selling transportation equipment, deciding to mount the semiconductor apparatus according to the present embodiment in the transportation equipment is advantageous for improving the performance of the transportation equipment. The semiconductor apparatus 111 is especially suitable for transportation equipment for which driving assistance and/or automatic driving is performed using information obtained by the semiconductor apparatus.

With reference to FIGS. 31B and 31C, a photoelectric conversion system and a mobile entity according to the present embodiment will now be described.

FIG. 31B is a diagram illustrating a photoelectric conversion system regarding a vehicle-mounted camera. A photoelectric conversion system 8 includes a photoelectric converter 80. The photoelectric converter 80 is a photoelectric converter (imaging device) described in any of the foregoing embodiments. The photoelectric conversion system 8 includes an image processing unit 801, which performs image processing on pieces of image data acquired by the photoelectric converter 80, and a parallax acquisition unit 802, which calculates a parallax (a parallax image phase difference) from the pieces of image data acquired by the photoelectric converter 80. The photoelectric conversion system 8 further includes a distance acquisition unit 803, which calculates a distance to a target object on the basis of the calculated parallax, and a collision determination unit 804, which determines whether there is a possibility of collision or not on the basis of the calculated distance. The parallax acquisition unit 802 and the distance acquisition unit 803 are examples of a distance information acquirer configured to acquire distance information about a distance to a target object. That is, the distance information is information about a parallax, a defocus amount, a distance to a target object, and the like. The collision determination unit 804 may determine the possibility of collision by using any of these kinds of distance information. The distance information acquirer may be embodied by dedicatedly-designed hardware or may be embodied by a software module. Alternatively, the distance information acquirer may be embodied by a field programmable gate array (FPGA), an application specific integrated circuit (ASIC), or the like, or may be embodied by a combination of them.

The photoelectric conversion system 8 is connected to a vehicle information acquisition apparatus 810 and is capable of acquiring vehicle information such as a vehicle speed, a yaw rate, a steering angle, and the like. The photoelectric conversion system 8 is connected to a control ECU 820, which is a controller configured to output a control signal for generating a braking force to act on the vehicle on the basis of the determination result of the collision determination unit 804. The photoelectric conversion system 8 is connected also to an alarming apparatus 830, which issues an alarm to the driver on the basis of the determination result of the collision determination unit 804. For example, if the determination result of the collision determination unit 804 indicates that the possibility of collision is high, the control ECU 820 performs vehicle control to avoid a collision or reduce damage by applying the brake, easing up on the accelerator, suppressing an engine output, or the like. The alarming apparatus 830 warns the user by, for example, sounding an alarm, displaying alarm information on a screen of a car navigation system or the like, or vibrating a seat belt or a steering wheel.

In the present embodiment, the photoelectric conversion system 8 captures an image of an area around the vehicle, for example, forward or rearward thereof.

A photoelectric conversion system performing imaging forward of a vehicle (an imaging range 850) is illustrated in FIG. 31C. The vehicle information acquisition apparatus 810 sends instructions to the photoelectric conversion system 8 or the photoelectric converter 80. With this configuration, it is possible to further improve the precision of distance measurement.

Although an example of performing control so as to avoid a collision with another vehicle has been described above, the photoelectric conversion system may be applied to control for performing automatic driving while following another vehicle, control for performing automatic driving with no deviation from the lane, or the like. Moreover, the scope of application of the photoelectric conversion system is not limited to a vehicle such as the user's vehicle; for example, it may be applied to a mobile entity (a moving apparatus) such as a vessel, an airplane, or an industrial robot. In addition, the scope of application of the photoelectric conversion system is not limited to a mobile entity; it may be applied to a wide variety of equipment using object recognition, for example, an intelligent transport system (ITS) or the like.

The embodiments described above can be modified as appropriate within a range of not departing from the spirit of the technical idea. The content of disclosure in this specification encompasses not only the matters that are explicitly described in this specification but also all matters that can be understood from this specification and the drawings attached to this specification. Moreover, a complementary set for a set of concepts described in this specification is also included in the content of disclosure in this specification. Specifically, for example, if there is a statement “A is larger than B” in this specification, even if a statement “A is not larger than B” is omitted, it can be said that a concept “A is not larger than B” is also disclosed in this specification. This is because, when there is a statement “A is larger than B”, this is premised on that a case where “A is not larger than B” is also considered.

The disclosed technique makes it possible to provide a protection circuit that offers improved protection characteristics while suppressing an increase in chip area size, in a semiconductor apparatus that includes the protection circuit.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-099665, filed Jun. 21, 2022, which is hereby incorporated by reference herein in its entirety.

What is claimed is:

1. A semiconductor apparatus, comprising:
a semiconductor layer having a first surface and a second surface and including, between the first surface and the second surface, a semiconductor element and a protection circuit;
a wiring layer disposed at a first-surface side of the semiconductor layer and electrically connected to the protection circuit or a plurality of wiring layers disposed at a first-surface side of the semiconductor layer and electrically connected to the protection circuit, the first-surface side being a side where the first surface is located; and
a first heat dissipation layer disposed between the wiring layer and the semiconductor layer or between a wiring layer that is closest to the semiconductor layer, among the plurality of wiring layers, and the semiconductor layer, and not electrically connected to the protection circuit, wherein
in a plan view taken at the first-surface side, the first heat dissipation layer is disposed at a position of overlapping with at least a part of the protection circuit.

2. The semiconductor apparatus according to claim 1, wherein
in a plan view taken at the first-surface side, a contact layer connecting the protection circuit and the wiring layer electrically is disposed inside a region surrounded by the first heat dissipation layer.

3. The semiconductor apparatus according to claim 1, wherein
in a plan view taken at the first-surface side, a plurality of contact layers connecting the protection circuit and the wiring layer electrically is disposed, and the first heat dissipation layer is disposed between the plurality of contact layers.

4. The semiconductor apparatus according to claim 1, wherein
in a plan view taken at the first-surface side, a contact layer connecting the protection circuit and the wiring layer electrically is disposed between a plurality of first heat dissipation layers each of which is the first heat dissipation layer.

5. The semiconductor apparatus according to claim 1, wherein
in a plan view taken at the first-surface side, the first heat dissipation layer is disposed at a position of overlapping with at least a part of a well region included in the protection circuit.

6. The semiconductor apparatus according to claim 1, wherein
in a plan view taken at the first-surface side, the first heat dissipation layer is disposed at a position of overlapping with at least a part of an active region included in the protection circuit.

7. The semiconductor apparatus according to claim 1, wherein
the first heat dissipation layer contains, at least, a single element alone of metal selected from the group consisting of tungsten, copper, aluminum, titanium, cobalt, and nickel, or an alloy including the metal.

8. The semiconductor apparatus according to claim 1, wherein
the wiring layer and the first heat dissipation layer contain metal, and
a main element of the wiring layer and a main element of the first heat dissipation layer are different from each other.

9. The semiconductor apparatus according to claim 1, wherein
an element isolation region and a second heat dissipation layer including metal are disposed between the first surface and the second surface,
the protection circuit includes the element isolation region,
the second heat dissipation layer is in contact with the element isolation region,
the protection circuit is disposed at a first depth from the first surface, and
the second heat dissipation layer is disposed at the first depth from the first surface.

10. The semiconductor apparatus according to claim 9, wherein
the second heat dissipation layer contains, at least, a single element alone of metal selected from the group consisting of tungsten, copper, aluminum, titanium, cobalt, and nickel, or an alloy including the metal, or a metal-and-polysilicon compound.

11. The semiconductor apparatus according to claim 1, wherein
the semiconductor element includes a peripheral circuit configured to process a signal detected by a photoelectric conversion portion.

12. The semiconductor apparatus according to claim 1, wherein
the semiconductor element includes a photoelectric conversion portion.

13. The semiconductor apparatus according to claim 12, wherein
light enters the photoelectric conversion portion through the second surface.

14. The semiconductor apparatus according to claim 13, wherein
a circuit substrate including a peripheral circuit configured to process a signal detected by the photoelectric conversion portion is stacked on the semiconductor layer.

15. The semiconductor apparatus according to claim 1, wherein
the first heat dissipation layer is electrically connected to a pad that is not electrically connected to the protection circuit.

16. A semiconductor apparatus, comprising:
a semiconductor layer having a first surface and a second surface and including, between the first surface and the second surface, a semiconductor element, a protection circuit, and an element isolation region; and
a second heat dissipation layer, wherein
the protection circuit includes the element isolation region,
the second heat dissipation layer is disposed in contact with the element isolation region between the first surface and the second surface and includes metal,
the protection circuit is disposed at a first depth from the first surface, and
the second heat dissipation layer is disposed at the first depth from the first surface.

17. A method for manufacturing a semiconductor apparatus, the semiconductor apparatus including
a semiconductor layer having a first surface and a second surface and including, between the first surface and the second surface, a photoelectric conversion portion and a protection circuit,
a light shielding film disposed at a first-surface side of the semiconductor layer, the first-surface side being a side where the first surface is located, and
a wiring layer disposed at the first-surface side of the semiconductor layer and electrically connected to the protection circuit or a plurality of wiring layers disposed at a first-surface side of the semiconductor layer and electrically connected to the protection circuit,
the method comprising:
forming the light shielding film between the wiring layer and the semiconductor layer or between a wiring layer that is closest to the semiconductor layer, among the plurality of wiring layers, and the semiconductor layer at a position of, in a plan view taken at the first-surface side, overlapping with at least a part of the photoelectric conversion portion; and
forming a first heat dissipation layer between the wiring layer and the semiconductor layer or between a wiring layer that is closest to the semiconductor layer, among the plurality of wiring layers, and the semiconductor layer at a position of, in a plan view taken at the first-surface side, overlapping with at least a part of the protection circuit, the first heat dissipation layer being not electrically connected to the protection circuit, wherein
the forming the light shielding film and the forming the first heat dissipation layer are executed concurrently.

18. Equipment comprising:
the semiconductor apparatus according to claim 1; and
at least one selected from the group comprising
an optical apparatus co-operable with the semiconductor apparatus;
a control apparatus configured to control the semiconductor apparatus;
a processing apparatus configured to process a signal outputted from the semiconductor apparatus;
a display apparatus configured to display information obtained by the semiconductor apparatus;
a storage apparatus configured to store information obtained by the semiconductor apparatus; and
a mechanical apparatus configured to operate based on information obtained by the semiconductor apparatus.

19. A substrate, comprising:
a semiconductor layer having a first surface and a second surface and including, between the first surface and the second surface, a semiconductor element and a protection circuit;
a wiring layer disposed at a first-surface side of the semiconductor layer and electrically connected to the protection circuit or a plurality of wiring layers disposed at a first-surface side of the semiconductor layer and electrically connected to the protection circuit, the first-surface side being a side where the first surface is located; and
a first heat dissipation layer disposed between the wiring layer and the semiconductor layer or between a wiring layer that is closest to the semiconductor layer, among the plurality of wiring layers, and the semiconductor layer, and not electrically connected to the protection circuit, wherein
in a plan view taken at the first-surface side, the first heat dissipation layer is disposed at a position of overlapping with at least a part of the protection circuit.
